(19) United States
(12) Patent Application Publication
(10) Pub. No.: US 2006/0091497 A1
(43) Pub. Date: May 4, 2006

(54) Semiconductor device

(75) Inventor: Masaharu Sato, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/302,399

(22) Filed: Dec. 14, 2005

(30) Foreign Application Priority Data
Jan. 1, 2004 (JP) 2004-380350

(51) Int. Cl. H01L 27/082

(52) U.S. Cl. 257/575

(57) ABSTRACT

A semiconductor device 100 includes a transistor, through which an electrical current flows via a first N-type buried region 106 and a second N-type buried region 108 having a conductivity type same as an N-type collector region 118 has. In semiconductor device 100, an N-type coupling region 107 that is a portion forming a second conductivity type region by an impact ionization when the transistor is in an operating state, is disposed on a path including the N-type collector region 118, the first N-type buried region 106 and the second N-type buried region 108.

The present application is based on Japanese Patent Application NO. 2004-380, 350, the content of which is incorporated hereinto by reference.

### BACKGROUND

1. Technical Field

The present invention relates to a semiconductor device.

2. Related Art

FIG. 19 is a cross-sectional view, showing structure of the conventional semiconductor device having a bipolar transistor formed on a substrate. The semiconductor device 10 includes a P-type substrate 12, an N-type region 14 formed thereon, an N-type buried region 16 formed between the P-type substrate 12 and the N-type region 14, a P-type base region 18 formed in the N-type region 14, an N-type emitter region 20 and a P-type base contact region 22 formed in the P-type base region 18, and an N-type collector region 24 formed in the N-type region 14. Here, the N-type emitter region 20, the P-type base region 18, and the N-type collector region 24 compose an NPN transistor.

FIG. 20 is a diagram, showing a relationship of an electrical voltage V_{c} of a collector of such NPN transistor and a current I_{c} flowing to the collector. When the electrical voltage V_{c} of the collector reaches an avalanche break-down voltage V_{b} between the collector and the base, a break-down is caused in the bipolar transistor, leading to commencing a flow of an electrical current I_{bd} flowing from the collector through the P-type base region 18 to the base. When the current I_{bd} is increased, an electric potential V_{be} of a portion right under the N-type emitter region 20 is also increased by I_{bd}×R_{b} because of a resistance component R_{b} of the P-type base region 18. The junction between the emitter and the base is switched on by the electrical potential V_{be} to allow an electric current flowing from the base to the emitter. An electrical voltage generated in this time is Vₜ. This starts the operation of the NPN transistor, allowing the electrical current I_{c} flowing therethrough. As NPN transistor starts its operation and the current I_{c} flows, electron injected from the N-type emitter region 20 to the P-type base region 18 increases, and the hole density is also increased with such increase of the electron, thereby commencing the increase in the effective base width. This increase causes reducing a width of a depleted layer between the collector and the base, thereby commencing a deterioration in the breakdown voltage. While a further increase in the current I_{c} also causes an increase in the base width, the presence of the N-type buried region 16 formed in the lower part inhibits the extension of the base width and also restricts a reduction in a width of the depleted layer, thereby inhibiting the decrease in the breakdown voltage. An electrical voltage generated in this time is V_{hold}.

Japanese Patent Laid-Open No. 2003-197,908 describes a semiconductor element, having a buried diffusion layer formed on the semiconductor substrate and a metal oxide semiconductor (MOS) transistor that is formed on the well region formed thereon.

Meanwhile, in the case that the V_{hold} is lower than the source voltage, if a snapback is once occurred in the bipolar transistor by an input of a pulse or the like, it is not restored to its former state even if the cause thereof disappears, and there is the fear that the current continues to flow. Therefore, it is preferable to have higher V_{hold}. However, the electrical voltage V_{hold} after the snapback is conventionally given by a concentration profile at a portion where the concentration on the current path considerably changes (a boundary (C) between the N-type buried region 16 and the N-type region 14). Therefore, it is difficult to easily achieve a considerable improvement in the breakdown voltage.

### SUMMARY OF THE INVENTION

According to one aspect of the present invention, there is provided a semiconductor device, including: a transistor, through which an electrical current flows via a buried region having a first conductivity type that is the same type of the conductivity as a collector region or a drain region has, wherein a portion that forms a second conductivity type region by an impact ionization when the transistor is in an operating state, is disposed on a path including the collector or drain region and the buried region.

Having such configuration, a configuration equivalent to a condition that a second transistor is formed on the above-described path is achieved, after the transistor is operated and a snapback is occurred, thereby providing an improved V_{hold} after the snapback. This provides an improved breakdown voltage of the transistor. In addition, having such configuration, a convergence point of the electric field in the semiconductor device can be dispersed into a plurality of components after the snapback, and therefore stresses in respective points can be relaxed, and a durability of the device can also be maintained.

In addition, in the semiconductor device according to the present invention, the transistor is configured to exhibit the transistor characteristics similar to that of the conventional transistors, before being in the operating state. Having this configuration, an element of a protection target can be protected without destroying thereof, when the transistor is employed for an electrostatic discharge (ESD) protection circuit.

In this case, a region including a collector (or a drain region) and a buried region can be divided in a direction normal to the electric current direction into a plurality of fragments along the aforementioned path, and the aforementioned portion can be formed in the divided fragment.

According to another aspect of the present invention, there is provided a semiconductor device including a transistor, including: a semiconductor substrate; a drift region of a first conductivity type formed on the semiconductor substrate; a buried region of the first conductivity type formed between the semiconductor substrate and the drift region, the buried region having higher impurity concentration than the drift region; a collector or drain region of the first conductivity type formed on a principal plane of the drift region; a base or body region of a second conductivity type; and an emitter or source region of the first conductivity type, wherein a coupling region of a first conductivity type is formed on a path including the collector or drain region and the buried region, the coupling region containing a first conductivity type impurity at a concentration lower than the collector or drain region or the buried region and higher than the drift region.

Having such configuration, larger electrical current can be flowed along the coupling region after the transistor is operated and a snapback is occurred, and then an impact ionization is occurred in a coupling region having an impurity concentration lower than the collector or the drain region or the buried region, thereby providing a function as a second transistor to these regions.

Here, in order to create the impact ionization in the coupling region after the snapback of the transistor to allow the collector or drain region, the buried region and the coupling region functioning as the second transistor, impurity concentrations in these regions, width of the coupling region along the electric current direction on the path or the like should be suitably controlled.

According to the present invention, a breakdown voltage can be improved after commencing the operation of the transistor in the semiconductor device including the transistor.

### BRIEF DESCRIPTION OF THE DRAWINGS

The above and other objects, advantages and features of the present invention will be more apparent from the following description taken in conjunction with the accompanying drawings, in which:

FIG. 1 is a cross sectional view of a semiconductor device according to the present invention, illustrating a configuration of a semiconductor device in an embodiment;

FIG. 2 is a diagram, showing a profile of an impurity concentration in the cross section broken along an arrow shown in FIG. 1;

FIGS. 3A and 3B are cross-sectional views of the semiconductor device according to the present invention, describing an operation of the semiconductor device in the embodiment of the present invention;

FIG. 4 is a cross sectional view of a semiconductor device according to the present invention, illustrating an effective base region in the operation of the transistor Q₁;

FIGS. 5A, 5B and 5C are diagrams, showing conditions of the N-type coupling region in the operation of the transistor Q₁;

FIG. 6 is a diagram, showing a profile of a potential difference in the cross section broken along the arrow shown in FIG. 1;

FIGS. 7A and 7B are circuit diagrams in the semiconductor device according to the embodiment of the present invention;

FIG. 8 is a graph, showing a relationship of the an electrical voltage V_{c} of the collector with an electrical current I_{c} flowing through the collector in the semiconductor device of the embodiment according to the present invention;

FIGS. 9A, 9B and 9C are cross-sectional views of the semiconductor device according to the present invention, illustrating a part of a procedure for manufacturing the semiconductor device in the embodiment of the present invention;

FIG. 10 is a schematic plan view of the semiconductor device according to the present invention;

FIG. 11 is a cross-sectional view of another exemplary configuration of the semiconductor device shown in FIG. 1;

FIG. 12A is a cross-sectional view a configuration of a semiconductor device in the embodiment according to the present invention, and FIG. 12B is a schematic plan view thereof;

FIG. 13A is a cross-sectional view a configuration of a semiconductor device in the embodiment according to the present invention, and FIG. 13B is a schematic plan view thereof;

FIG. 14A is a cross-sectional view a configuration of a semiconductor device in the embodiment according to the present invention, and FIG. 14B is a schematic plan view thereof;

FIG. 15A is a cross-sectional view a configuration of a semiconductor device in the embodiment according to the present invention, and FIG. 15B is a schematic plan view thereof;

FIG. 16 is a cross-sectional view of an alternative semiconductor device in the embodiment according to the present invention;

FIG. 17 is a cross-sectional view of an alternative semiconductor device in the embodiment according to the present invention;

FIG. 18 is a cross-sectional view of an alternative semiconductor device in the embodiment according to the present invention;

FIG. 19 is a cross-sectional view of a conventional semiconductor device;

FIG. 20 is a graph, showing a relationship of an electrical voltage V_{c} of the collector with an electrical current I_{c} flowing through the collector in a conventional semiconductor device.

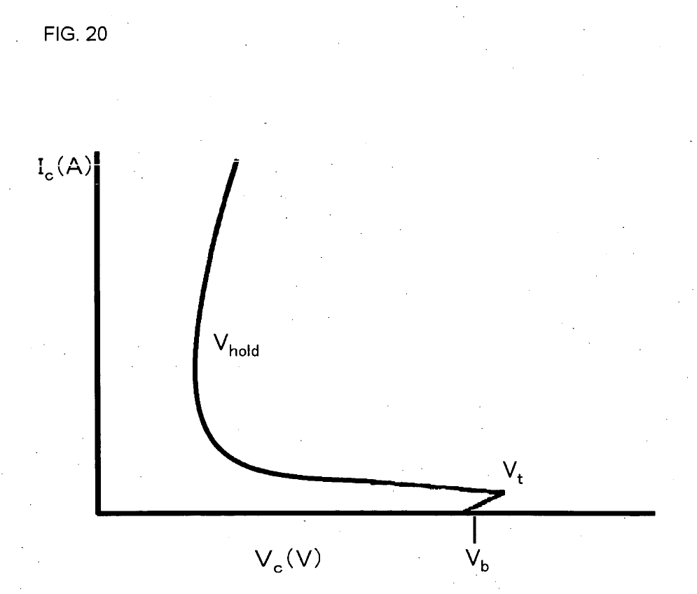

### DETAILED DESCRIPTIONS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows in further detail, in reference to the annexed figures. In all figures, identical numeral is assigned to an element commonly appeared in the figures, and the detailed description thereof will not be presented.

A semiconductor device according to the present embodiment includes a transistor, through which an electrical current flows via a buried region of the first conductivity type that is the same type of the conductivity as a collector region or a drain region has. In the semiconductor device, a coupling region that is capable of functioning as a second conductivity type region by an impact ionization when the transistor is in an operating state, is disposed on a path including the collector or drain region and the buried region.

In the following embodiments, the transistor is employed as an ESD protection circuit. In the following embodiments, cases defining the N-type as the first conductivity type and the P-type as the second conductivity type will be described.

### FIRST EMBODIMENT

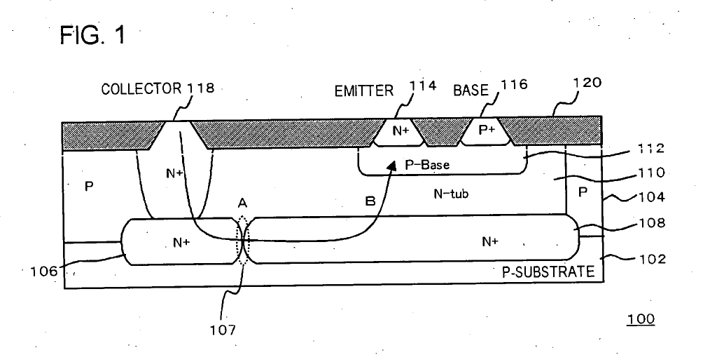

FIG. 1 is a diagram, schematically illustrating a configuration of a semiconductor device according to the present embodiment. In the present embodiment, the semiconductor device includes an NPN bipolar transistor (hereinafter referred to as “transistor Q₁”).

The semiconductor device 100 includes a P-type substrate 102, a P-type epitaxial layer 104 formed on the P-type substrate 102, an N-type drift region 110 formed in the P-type epitaxial layer 104, a first N-type buried region 106 and a second N-type buried region 108 both formed between the P-type substrate 102 and the N-type drift region 110, an N-type coupling region 107 formed between the first N-type buried region 106 and the second N-type buried region 108, a P-type base region 112 formed in the N-type drift region 110, an N-type emitter region 114 and a P-type base contact region 116 both formed on the P-type base region 112, an N-type collector region 118 formed on the first N-type buried region 106, and an insulating oxide film 120 formed on the P-type epitaxial layer 104. An N-type impurity is continuously diffused over the first N-type buried region 106, the N-type coupling region 107 and the second N-type buried region 108.

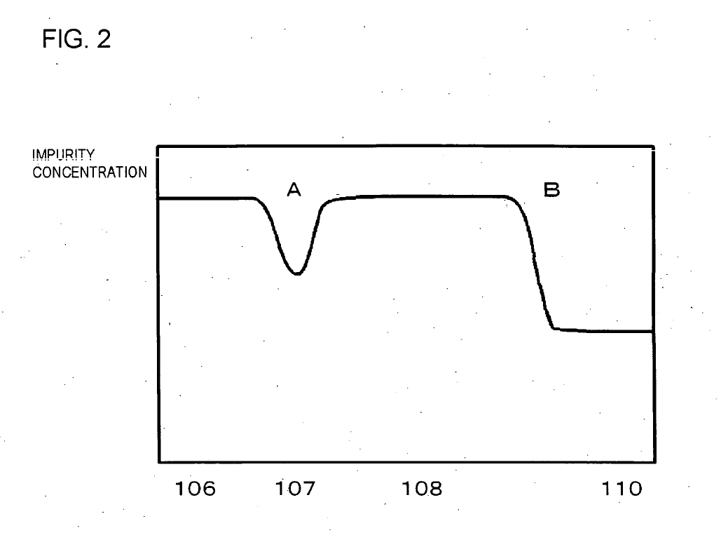

FIG. 2 is a diagram, showing an impurity concentration in the surface broken along an arrow shown in FIG. 1. In the N-type coupling region 107 between the first N-type buried region 106 and the second N-type buried region 108 (indicated as “A” in the diagram), the impurity concentration is lower than the first N-type buried region 106 and the second N-type buried region 108. Further, differences in the impurity concentration are also created in the boundary between the second N-type buried region 108 and the N-type drift region 110 (indicated as “B” in the diagram).

In this case, the first N-type buried region 106 and the second N-type buried region 108 have substantially the same impurity concentration. Further, the first N-type buried region 106 and the second N-type buried region 108 have substantially the same impurity profile. Peak impurity concentrations of the first N-type buried region 106 and the second N-type buried region 108 may be, for example, equal to or higher than 1×10¹⁸ cm⁻³. This reduces a resistance in the case of flowing an electrical current through the first N-type buried region 106 and the second N-type buried region 108. Further, an extension of the effective P-type base region 112 in the operation of the transistor Q₁ can be prevented by the presence of the second N-type buried region 108. While the peak impurity concentrations of the first N-type buried region 106 and the second N-type buried region 108 are not particularly limited, the peak impurity concentrations thereof may be, for example, equal to or lower than 1×10²⁰ cm⁻³.

The N-type coupling region 107 is formed so as to have a lower impurity concentration than the first N-type buried region 106 and the second N-type buried region 108. Having this configuration, a portion, which behaves as a P-type region by an impact ionization in the operation of the transistor Q₁, may be formed in the N-type coupling region 107. Further, the N-type coupling region 107 is formed so as to have higher impurity concentration than the N-type drift region 110. This allows an electrical current preferentially flowing through the N-type coupling region 107.

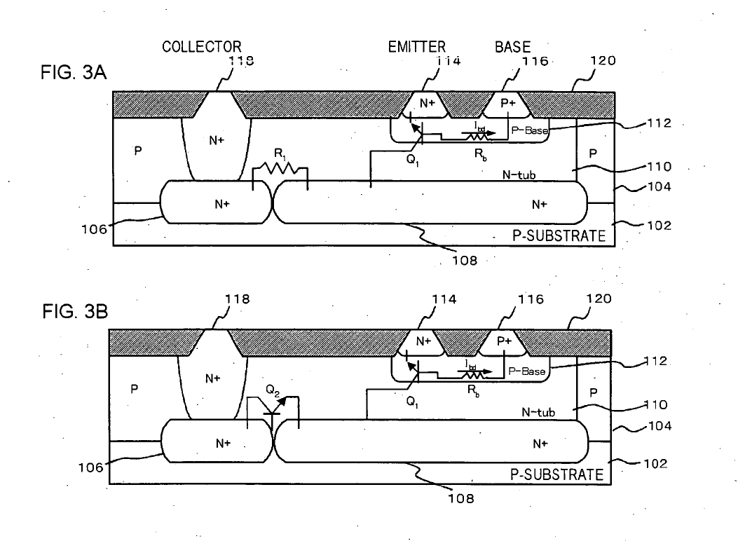

Next, an operation of the semiconductor device 100 in the present embodiment will be described in reference to FIGS. 3A and 3B.

First, a depleted layer between the base and the collector is broadened as increasing an electrical voltage across the collector. Once the electrical voltage V_{c} across the collector reaches an avalanche breakdown voltage V_{b} between the collector and the base, a breakdown is occurred at the transistor Q₁, and an electrical current I_{bd} starts to flow to the base from the collector through the P-type base region 112. When the electrical current I_{bd} is increased, an electric potential V_{be} at a region right under the N-type emitter region 114 is also increased by I_{bd}×R_{b}, due to a resistance component R_{b} in the P-type base region 112. The junction between the emitter and the base is switched on by the electrical potential V_{be} to allow an electric current flowing from the base to the emitter. The transistor Q₁ starts its operation by such process to allow an electrical current I_{c} flowing. In this occasion, the N-type coupling region 107 between the first N-type buried region 106 and the second N-type buried region 108 functions as a resistor R1, and a voltage drop by I_{c}×R₁ is occurred between the first N-type buried region 106 and the second N-type buried region 108 (FIG. 3A).

As the electrical current I_{c} is increased by operating the transistor Q₁, electron injected from the N-type emitter region 114 to the P-type base region 112 is increased, and the hole density is also increased according to such increase, and thus an effective base width is started to be increased. This reduces the width of the depleted layer between the collector and the base, and thus the breakdown voltage is stared to be reduced.

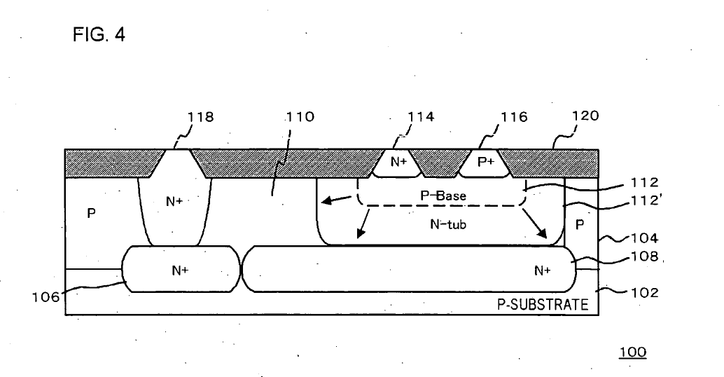

FIG. 4 is a cross-sectional view of the device, showing an effective base region 112′ during the operation of the transistor Q₁. While a further increase in the current I_{c} also causes an increase in the base width, the presence of the second N-type buried region 108 formed in the lower part inhibits the extension of the base width and also restricts a reduction in the width of the depleted layer. This also reduces the deterioration of the breakdown voltage.

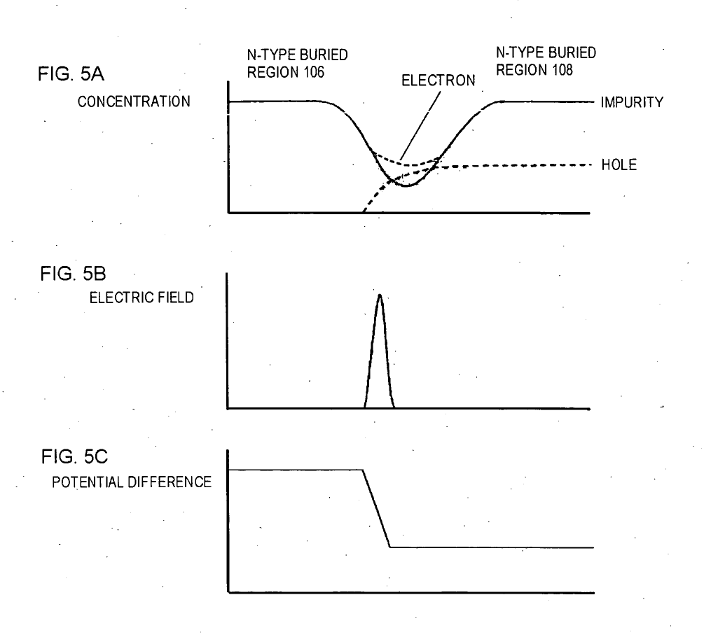

In the present embodiment, an electron density in the second N-type buried region 108, the N-type coupling region 107 and the first N-type buried region 106 is also increased as the electrical current I_{c} is increased, and thus the electron concentration is higher than the concentration of the N-type impurity in the N-type coupling region 107. Then, an impact ionization is occurred in a boundary region between the N-type coupling region 107 and the first N-type buried regions 106 and the second N-type buried region 108 to start generating holes. The holes generated here is transferred toward a negative potential side (a direction from the first N-type buried region 106 to the second N-type buried region 108). When the electrical current I_{c} is further increased, the hole density in the N-type coupling region 107 is further increased. This condition is shown in FIG. 5A. Having this configuration, the first N-type buried region 106, the N-type coupling region 107 and the second N-type buried region 108 substantially function as an NPN transistor (hereinafter referred to as transistor Q₂), which utilizes the N-type coupling region 107 as a base, the first N-type buried region 106 and the second N-type buried region 108 as the collector and the emitter, respectively, and the hall current as the base current. Therefore, depleted layers are drastically broadened between the First N-type buried region 106 and the N-type coupling region 107, and between the N-type coupling region 107 and the second N-type buried region 108, and thus electric field is converged at the N-type coupling region 107 (FIG. 5B), thereby producing a potential difference (FIG. 5C).

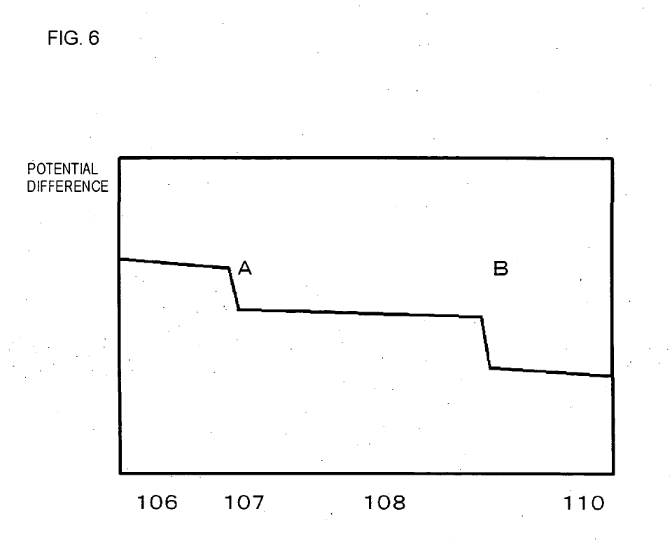

FIG. 6 is a graph, showing potential differences in the cross section broken along an arrow shown in FIG. 1. The semiconductor device 100 in the present embodiment includes a considerable potential differences produced at the points A and B (see FIG. 1). Therefore, a decrease in the breakdown voltage occurred after the snapback back after starting the operation of the transistor Q₁ can be inhibited.

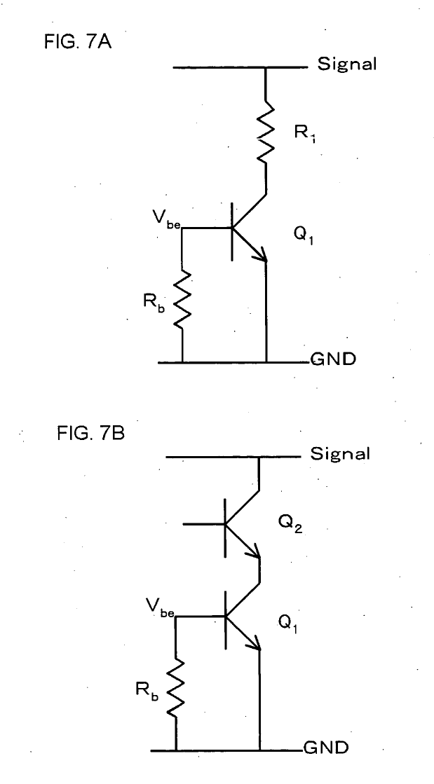

FIGS. 7A and 7B are circuit diagrams of the semiconductor device 100 according to the present embodiment. FIG. 7A is a circuit diagram, showing a condition that the N-type coupling region 107 functions as a resistor R₁. FIG. 7B is a circuit diagram, showing a condition that the first N-type buried region 106, the N-type coupling region 107 and the second N-type buried region 108 function as the transistor Q₂. As such, the semiconductor device 100 in the present embodiment forms a circuit structure equivalent to that having two NPN transistors coupled in series, when higher current flows through the first N-type buried region 106, the N-type coupling region 107 and the second N-type buried region 108.

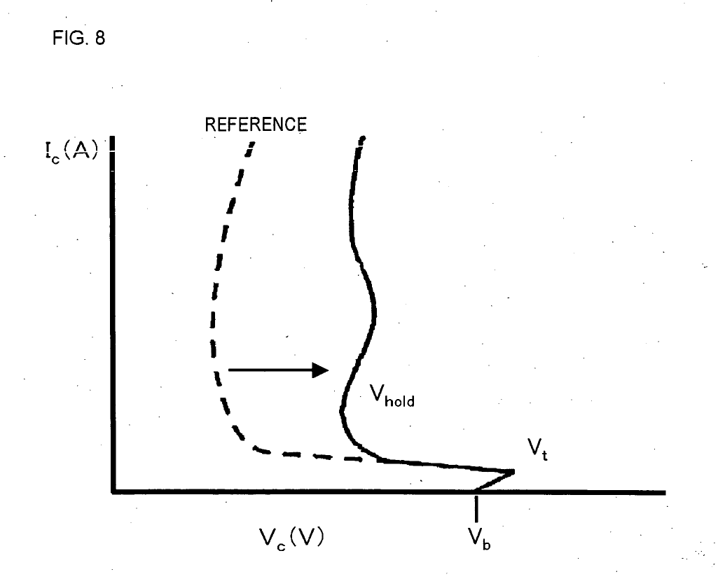

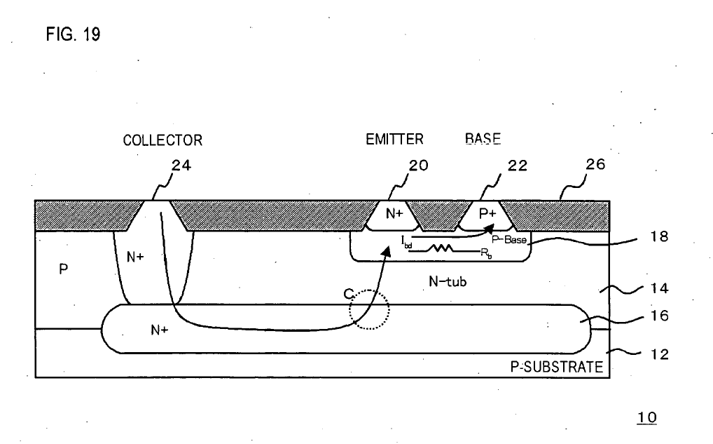

FIG. 8 is a graph, showing a relationship of an electrical voltage V_{c} across the collector and an electrical current I_{c} flowing through the collector in the semiconductor device 100 according to the present embodiment. In this graph, a relationship of an electrical voltage V_{c} across the collector and an electrical current I_{c} flowing through the collector in the conventional semiconductor device shown in FIG. 19 is also shown by a dashed line as a reference.

The semiconductor device 100 in the present embodiment exhibits the transistor characteristics similar to that of the conventional transistors, until the electrical voltage V_{c} of the collector reaches Vₜ to start the operation of the transistor Q₁. On the other hand, once the transistor Q₁ is operated, the first N-type buried region 106, the N-type coupling region 107 and the second N-type buried region 108 composes the transistor Q₂, thereby increasing the V_{hold}. Having this configuration, the V_{hold} can be maintained at higher level than the source voltage after the snapback back, and therefore, the continues flowing of the electrical current can be prevented.

Further, according to the semiconductor device 100 in the present embodiment, breakdown voltage can be enhanced, and the increase of the electrical voltage beyond the Vₜ can be prevented even if the electrical current is increased. Therefore, a target element to be protected can be protected without destroying thereof, when the transistor is employed as the electrostatic discharge (ESD) protection circuit.

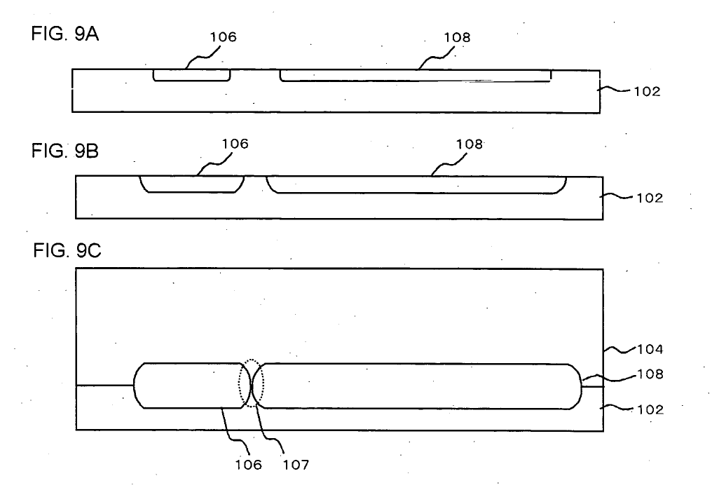

FIGS. 9A to 9C are cross-sectional views, showing a part of the manufacturing procedure of the semiconductor device 100 in the present embodiment. First, an N-type impurity such as As or Sb is ion-implanted into the P-type substrate 102 to form a first N-type buried region 106 and a second N-type buried region 108 (FIG. 9A). In this time, the impurity concentration in the N-type coupling region 107 formed between the first N-type buried region 106 and the second N-type buried region 108 can be adequately controlled by controlling the injecting region and the impurity concentration in the first N-type buried region 106 and the second N-type buried region 108. This can preferably produce the impact ionization in the N-type coupling region 107.

Subsequently, an inclusion process is conducted to diffuse the impurity in the first N-type buried region 106 and the second N-type buried region 108 (FIG. 9B).

Subsequently, a P-type epitaxial layer 104 is formed on the P-type substrate 102 at, for example, a normal pressure and at a relatively lower temperature of about 1,050 degree C. (FIG. 9C). This prevents an automated-doping of the N-type impurity from the first buried region 106 and the second buried region 108, thereby facilitating a control of the concentration in the N-type coupling level region 107. Further, in this occasion, the impurity in the first N-type buried region 106 and the second N-type buried region 108 further diffuse to form the N-type coupling region 107 between the first N-type buried region 106 and the second N-type buried region 108.

Then, an ion implantation of an impurity is conducted to form an N-type drift region 110, an N-type collector region 118, a P-type base region 112, an N-type emitter region 114, and a P-type base contact region 116. The semiconductor device 100 having the configuration shown in FIG. 1 is thus obtained.

As such, according to the manufacturing procedure for the semiconductor device 100 in the present embodiment, the first N-type buried region 106 and the second N-type buried region 108 can be formed without requiring an additional complicated operations, and then these regions can be coupled through the N-type coupling region 107 having lower impurity concentration than these regions.

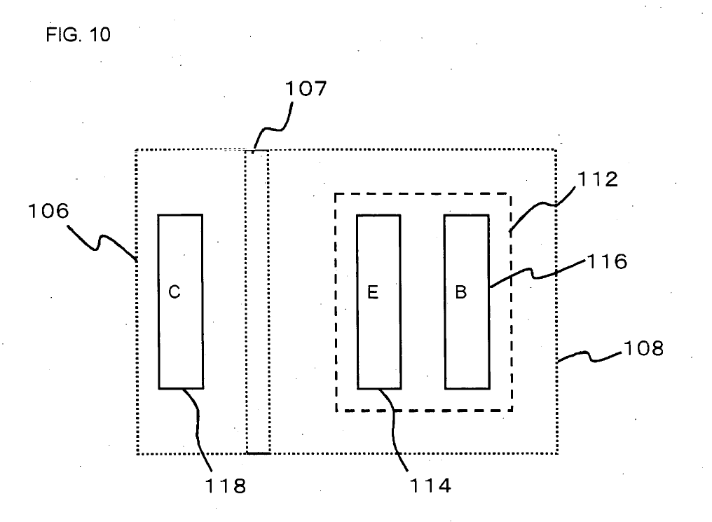

FIG. 10 is a schematic plan view of the semiconductor device 100. In this diagram, arrangements of the first N-type buried region 106, the N-type coupling region 107, the second N-type buried region 108, the P-type base region 112, the N-type emitter region 114, the P-type base contact region 116 and the N-type collector region 118 are schematically illustrated. The N-type coupling region 107 is formed between the first N-type buried region 106 and the second N-type buried region 108.

Next, preferable configuration of the semiconductor device 100 will be described. In order to form a P-type region in the N-type coupling region 107 by the impact ionization when the transistor Q₁ is in an operating state and a larger electrical current flows trough the N-type emitter region 114 from the N-type collector region 118, it is necessary to preferably control a distance between the first N-type buried region 106 and the second N-type buried region 108 or an impurity concentration in the N-type coupling region 107.

Further, the N-type coupling region 107, which is a divided region of the first N-type buried region 106 and the second N-type buried region 108, is formed at a location where the effective base region 112′ (see FIG. 4) is not in contact with the first N-type buried region 106 during the operation of the transistor Q₁. Here, the effective base region 112′ is a region where the P-type base region 112 is effectively broadened by the Kirk effect under the condition of flowing a higher current through the transistor Q₁. In this time, most electrical current flows through the effective base region 112′ from the second N-type buried region 108 to the N-type emitter region 114 and the P-type base contact region 116. If the first N-type buried region 106 contacts with the effective base region 112′ during the operation of the transistor Q₁, an electrical current directly flows to the effective base region 112′ from the first N-type buried region 106 and no electrical current flows through the N-type coupling region 107, and thus the impact ionization as have been described above does not occur in the N-type coupling region 107.

For example, a spacing in the transverse direction between the P-type base region 112 and the N-type coupling region 107 at the time the transistor Q₁ is in non-operating state can be wider than a spacing in the layer-stacking direction between the P-type base region 112 and the second N-type buried region 108 at the time the transistor Q₁ is in non-operating state. Even if the transistor Q₁ is in an operating state, and the effective base region 112′ is broadened, the broadening of the effective base region 112′ in the layer-stacking direction can be inhibited by the presence of the second N-type buried region 108. At the same time, a broadening thereof in the transverse direction is also reduced to the similar distance. Therefore, the contact of the effective base region 112′ with the first N-type buried region 106 during the operation of the transistor Q₁ can be avoided by providing more wider spacing between the P-type base region 112 and the N-type coupling region 107 in the transverse direction than the spacing between the P-type base region 112 and the second N-type buried region 108 in the layer-stacking direction.

Further, functional characteristics of the N-type coupling region 107 can be determined by the electron concentration flowing trough the N-type coupling region 107 and the impurity concentration in the N-type coupling region 107, when an electrical current flows trough the transistor Q₁. When the N-type impurity concentration in the N-type coupling region 107 is higher than the electron concentration therein, the N-type coupling region 107 functions as an ordinary conductor, and substantially no potential difference is occurred among the first N-type buried region 106, the N-type coupling region 107 and the second N-type buried region 108. On the other hand, when the N-type impurity concentration in the N-type coupling region 107 is reduced to a level that is lower than the electron concentration therein, a potential difference is created among the first N-type buried region 106, the N-type coupling region 107 and the second N-type buried region 108.

Therefore, if the N-type impurity concentration in the N-type coupling region 107 is excessively lower, the electron concentration is easily increased to a level that is higher than the N-type impurity concentration, and thus a potential difference is created at an earlier stage, thereby increasing Vₜ across the transistor Q₁. When such condition is established, the transistor Q₁ no longer functions as the ESD protection circuit. In such point of view, the impurity concentration in the N-type coupling region 107 may be selected to be, for example, equal to or higher than 5×10¹⁵ cm⁻³. On the contrary, when the N-type impurity concentration in the N-type coupling region 107 is excessively higher, the potential difference is not easily created among the first N-type buried region 106, the N-type coupling region 107 and the second N-type buried region 108, and thus these regions do not function as the transistor Q₂ after the snapback of the transistor Q₁. In such point of view, the impurity concentration in the N-type coupling region 107 may be selected to be, for example, equal to or lower than 1×10¹⁷ cm⁻³. Further, the first N-type buried region 106 and the second N-type buried region 108 may be configured that respective impurity tails are coupled in the N-type coupling region 107 having the above-described concentration.

Here, in order to cause the impact ionization in the portion of the N-type coupling region 107, the concentration difference between the minimum concentration of the N-type impurity in the coupling portion and the peak concentration in the first N-type buried region 106 and the second N-type buried region 108 is required to be equal to or higher than a predetermined value. Giving the minimum impurity concentration of the N-type coupling region 107 as Cₐ, and the peak impurity concentration in the first N-type buried region 106 and the second N-type buried region 108 as C_{b}, it is preferable to satisfy C_{b}/Cₐ≧10.

The semiconductor device 100 may have, for example, the following configuration. Having such configuration, the N-type coupling region 107 functions as a resistor before starting the operation of the transistor Q₁, and then after starting the operation of the transistor Q₁, the first N-type buried region 106, the N-type coupling region 107 and the second N-type buried region 108 function as the transistor Q₂, thereby allowing to maintain V_{hold} at higher level.

The peak impurity concentration in the first N-type buried region 106 and the second N-type buried region 108: 7×10¹⁸ cm⁻³;

the impurity concentration of the N-type coupling region 107: 1.5×10¹⁶ cm⁻³;

spacing between the first N-type buried region 106 and the second N-type buried region 108 during the injection of the impurity: 12 μm;

the thickness of the P-type epitaxial layer 104: 10 μm;

the width of the P-type base region 112 in the non-operating status of the transistor Q₁: 7 μm in the transverse direction; and

the width of the P-type base region 112 effectively acting in the operating condition of the transistor Q₁ operation: 11 μm in the transverse direction.

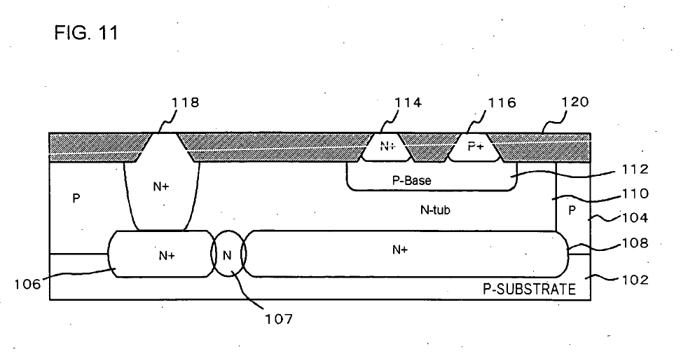

FIG. 11 is a cross-sectional view, showing another example of the semiconductor device 100 shown in FIG. 1. In the above embodiment, the example of forming the first N-type buried region 106 and the second N-type buried region 108 by the ion implantation of the N-type impurity, and forming the N-type coupling region 107 by diffusing the impurity in these regions has been described. In other example, N-type coupling region 107 can be formed by separately conducting an ion implantation in the region for forming the N-type coupling region 107 after conducting the ion implantation over the first N-type buried region 106 and the second N-type buried region 108. Preferable range of the impurity concentration and/or the formation region for the first N-type buried region 106, the N-type coupling region 107 and the second N-type buried region 108 in this case may be similar to that described above.

### SECOND EMBODIMENT

In the present embodiment, the semiconductor device 100 further includes a preventing region, which is formed between the N-type coupling region 107 and the P-type base region 112, and is capable of preventing a broadening of the P-type base region 112. Having such configuration, even if the effective base region 112′ is broadened during the operation of the transistor Q₁, the broadening thereof in the transverse direction can be prevented by the preventing region. Having this configuration, even though the P-type base region 112 and the N-type coupling region 107 are arranged in relatively closed positions, an electrical current flows through N-type coupling region 107 when a larger electrical current flows to the N-type emitter region 114 from the N-type collector region 118, and therefore an impact ionization is generated in the N-type coupling region 107.

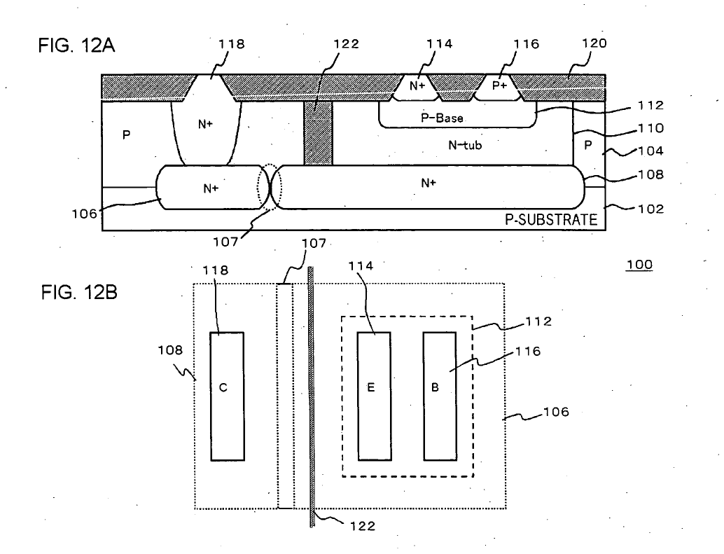

FIGS. 12A and 12B are diagrams, showing a configuration of the semiconductor device 100 in the present embodiment. FIG. 12A represents a cross-sectional view, and FIG. 12B represents a schematic plan view. The semiconductor device 100 further includes an insulating separating portion 122, in addition to the configuration described in first embodiment in reference to FIG. 1. The insulating separating portion 122 is formed by forming a splitting trench between the N-type coupling region 107 and the P-type base region 112, and plugging the splitting trench with an insulating material.

Having this configuration, the position for forming the N-type coupling region 107 can be determined without considering the broadening of the effective base region 112′ during the operation of the transistor Q₁. Therefore, the semiconductor device 100 can be miniaturized.

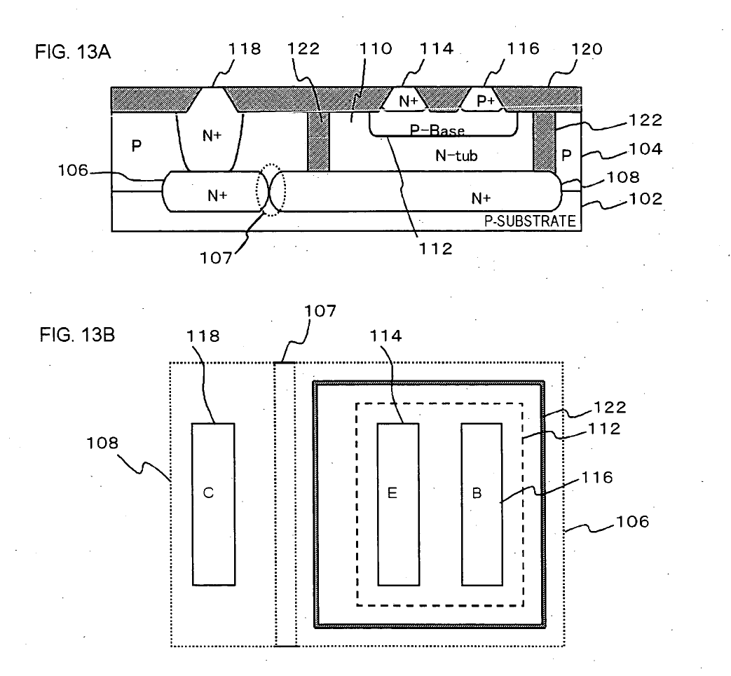

FIGS. 13A and 13B are diagrams, showing other configuration of an insulating separating portion 122. FIG. 13A represents a cross-sectional view, and FIG. 13B represents a schematic plan view. As such, even if the configuration of surrounding the P-type base region 112 with the insulating separating portion 122 is presented, the broadening of the effective base region 112′ during the operation of the transistor Q₁ can be prevented, and therefore a contact of the effective base region 112′ with the first N-type buried region 106 can be prevented.

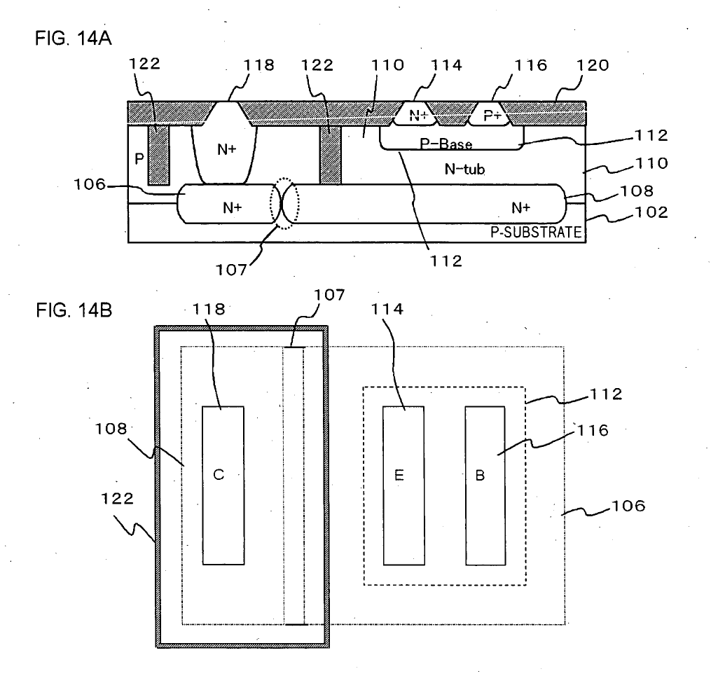

FIGS. 14A and 14B are diagrams, showing other configuration of an insulating separating portion 122. FIG. 14A represents a cross-sectional view, and FIG. 14B represents a schematic plan view. As such, even if the configuration of surrounding the N-type coupling region 107 and the first N-type buried region 106 with the insulating separating portion 122 is presented, the broadening of the effective base region 112′ during the operation of the transistor Q₁ can be prevented, and therefore a contact of the effective base region 112′ with the first N-type buried region 106 can be prevented.

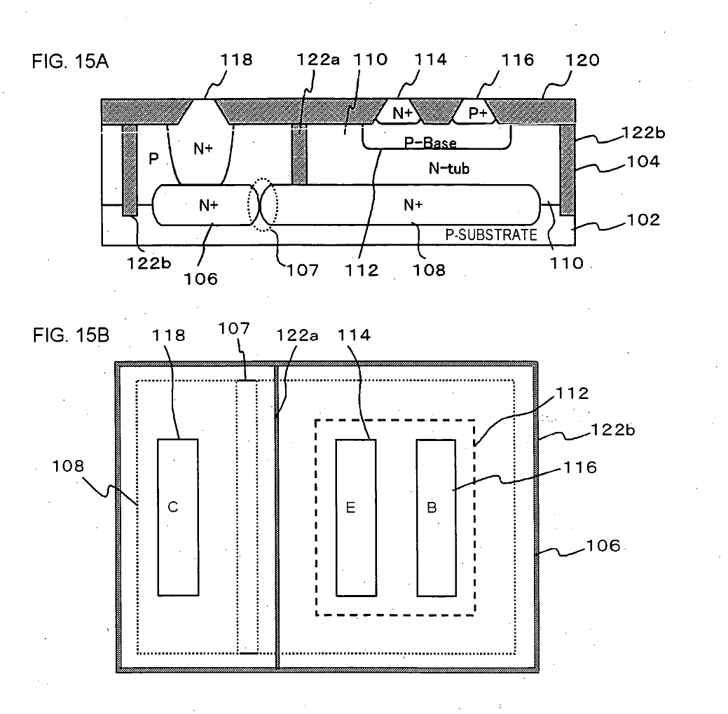

FIGS. 15A and 15B are diagrams, showing other configuration of an insulating separating portion 122. FIG. 15A represents a cross-sectional view, and FIG. 15B represents a schematic plan view. As such, even if the configuration of dividing and surrounding the P-type base region 112, and the N-type coupling region 107 and the first N-type buried region 106 with the first insulating separating portion 122a and the second insulating separating portion 122b is presented, the broadening of the effective base region 112′ during the operation of the transistor Q₁ can be prevented, and therefore a contact of the effective base region 112′ with the first N-type buried region 106 can be prevented.

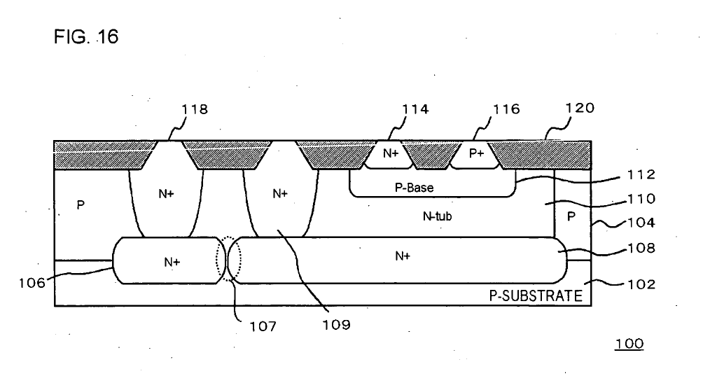

FIG. 16 is a cross-sectional view, showing other example of the semiconductor device 100 in the present embodiment. In this case, the semiconductor device 100 has an N-type region for isolation 109, in place of the insulating separating portion 122 shown in FIG. 12A. In this case, an exemplary case of forming the N-type region for isolation 109 as having a depth that reaches the second N-type buried region 108 is illustrated. The N-type region for an isolation 109 can be formed by an ion implantation, simultaneously with forming the N-type collector region 118. Having this configuration, the position for forming the N-type coupling region 107 can be determined without considering the broadening of the effective base region 112′ during the operation of the transistor Q₁. Therefore, the semiconductor device 100 can be miniaturized.

Further, N-type region for isolation 109 can also be formed to have a depth, which is shallower than the N-type collector region 118 and does not reach the second N-type buried region 108. Having such configuration, the broadening of the effective base region 112′ during the operation of the transistor Q₁ can be prevented. This can provide miniaturization of the semiconductor device 100.

### THIRD EMBODIMENT

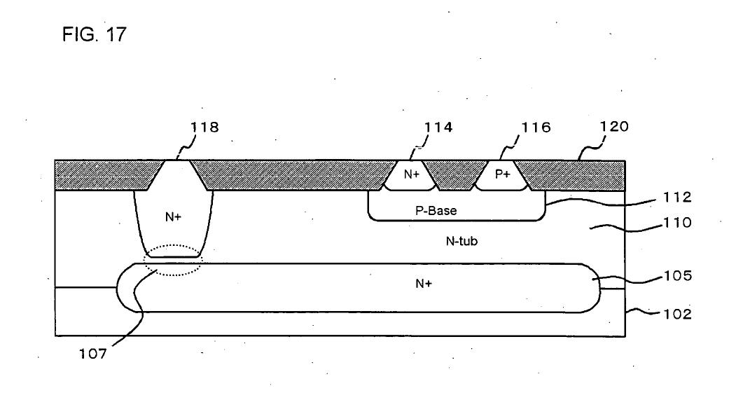

FIG. 17 is a cross-sectional view, showing a configuration of the semiconductor device in the present embodiment. The form has been described in first embodiment and second embodiment, in which a buried region formed between the P-type substrate 102 and the N-type drift region 110 is divided into the first N-type buried region 106 and the second N-type buried region 108, and the N-type coupling region 107 is formed therebetween. In the present embodiment, the semiconductor device 100 includes the N-type buried region 105, instead of the first N-type buried region 106 and the second N-type buried region 108. Further, the N-type coupling region 107 is formed between the N-type collector region 118 and the N-type buried region 105.

Having such configuration, an electrical current flows through N-type coupling region 107 when a larger electrical current flows to the N-type emitter region 114 from the N-type collector region 118 during the operation of the transistor Q₁, and therefore an impact ionization is generated in the N-type coupling region 107. This provides advantageous effects similar to that described in first embodiment.

Concerning the N-type coupling region 107, an N-type diffusion layer is formed on the surface of the N-type drift region 110 by, for example, an ion implantation, and thereafter, such N-type diffusion layer is diffused into the N-type drift region 110 to form the N-type collector region 118. Although the N-type buried region 105 is also diffused in this time, the N-type coupling region 107 can be formed by suitably controlling the diffusion condition.

Further, in the present embodiment, preventing regions such as the insulating separating portion 122, the N-type region for isolation 109 and the like can be formed between the P-type base region 112 and the N-type collector region 118, similarly as described in second embodiment. This provides advantageous effects similar to that being obtainable in second embodiment.

### FOURTH EMBODIMENT

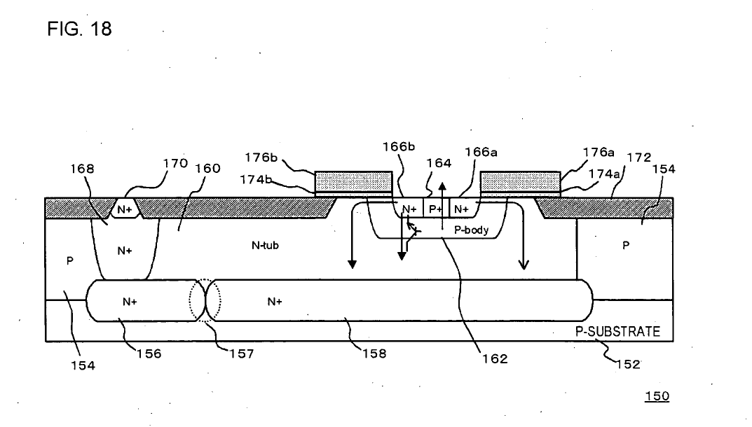

FIG. 18 is a cross-sectional view, showing a configuration of the semiconductor device in the present embodiment. In the present embodiment, the semiconductor device includes a vertical double-diffused MOS (VDMOS) transistor (hereinafter referred to as transistor Q₁).

A semiconductor device 150 includes: a P-type substrate 152; a P-type epitaxial layer 154 formed on the P-type substrate 152; an N-type drift region 160 formed in the P-type epitaxial layer 154; a first N-type buried region 156 and a second N-type buried region 158 formed between the P-type substrate 152 and the N-type drift region 160; an N-type coupling region 157 formed between the first N-type buried region 156 and the second N-type buried region 158; a P-type body region 162 formed in the N-type drift region 160; a P-type body contact region 164, an N-type source region 166a and an N-type source region 166b, all formed on the P-type body region 162; an N-type drain region 168 formed on the first N-type buried region 156; an N-type drain contact region 170 formed on the N-type drain region 168; and an insulating oxide film 172 formed on the P-type epitaxial layer 154. In addition, the semiconductor device 150 further includes agate insulating film 174a and a gate insulating film 174b that are formed on the surface of the P-type epitaxial layer 154, and a gate electrode 176a and a gate electrode 176b that are formed on the gate insulating film 174a and the gate insulating film 174b, respectively. An N-type impurity is continuously diffused over the first N-type buried region 156, the N-type coupling region 157 and the second N-type buried region 158.

In the present embodiment, the first N-type buried region 156, the N-type coupling region 157 and the second N-type buried region 158 have profiles of the impurity concentrations similar to that of the first N-type buried region 106, the N-type coupling region 107 and the second N-type buried region 108, respectively, all of which are described in first embodiment.

Next, an operation of the semiconductor device 150 in the present embodiment will be described. In operating the transistor Q₁, the surface of the P-type body region 162 right under the gate is inversed by a gate voltage, and thus an electron flows from the source through the P-type body region 162 to the N-type drift region 160. The electron that has entered into the N-type drift region 160 flows into the second N-type buried region 158 that has a lower electrical resistance, working as a drain electrical current, and thus the configuration functions as a MOS transistor. Meanwhile, the transistor Q₁ in the present embodiment, has a parasitic NPN transistor composed of an N-type source region 166a or an N-type source region 166b/a P-type body region 162/an N-type drift region 160. As the drain voltage is increased, a break-down is occurred between the N-type drift region 160 and the P-type body region 162. While the drain electrical current flows to the P-type body contact region 164 from the P-type body region 162 as a result thereof, the electric potential right under the N-type source region 166a or the N-type source region 166b are increased by an influence of the resistance component thereof, thereby starting an operation of the parasitic NPN transistor.

Hereafter, an electrical current flows through the N-type coupling region 157 when a larger electrical current drifts to the N-type source region 166a or the N-type source region 166b from the N-type drain region 168, causing the impact ionization in the N-type coupling region 157. Having this configuration, V_{hold} of the transistor Q₁ can be increased, similarly as described in first embodiment, and similar advantageous effects can be obtained.

The descriptions of the present invention have been made on the basis of the embodiments illustrated above. It should be understood by a person having ordinary skills in the art that the disclosure of these preferred embodiments are presented for the purpose of the illustration only, and combinations of these subject matters and/or the processing steps thereof may be modified, and the modified combinations are also within the scope of the invention.

While the above-mentioned embodiment illustrates the configuration, in which the region on the path including the collector or drain region and the buried region is divided in one location, an alternative configuration, in which such region on the path is divided into a plurality of components, may also be employed. In other words, a configuration having a plurality of N-type coupling regions 107 along the path may be employed. By increasing number of the partitions, V_{hold} of the semiconductor device 100 is given by a multiplication of the potential differences at respective path points, and therefore it can be concluded that V_{hold} can be further improved by increasing number of the partitions.

It is apparent that the present invention is not limited to the above embodiment, and may be modified and changed without departing from the scope and spirit of the invention.

What is claimed is:

1. A semiconductor device, comprising:
a transistor, through which an electrical current flows via a buried region having a first conductivity type that is the same type of the conductivity as a collector region or a drain region has,
wherein a portion that is capable of functioning as a second conductivity type region by an impact ionization when said transistor is in an operating state, is disposed on a path including said collector or drain region and said buried region.

2. The semiconductor device according to claim 1, wherein said buried region is formed as being divided into a plurality of fragments along said path, and wherein said portion is formed between said plurality of fragments of said buried regions.

3. The semiconductor device according to claim 1, wherein said portion is composed of a low concentration region, which contains a first conductivity type impurity at a concentration lower than a peak impurity concentration in said buried region.

4. The semiconductor device according to claim 3, wherein a relationship of:
C_{b}/Cₐ≧10
is satisfied,
where Cₐ is a concentration of the impurity in said low concentration region and C_{b} is a peak impurity concentration in said buried region.

5. The semiconductor device according to claim 3, wherein a drift region of the first conductivity type is formed between a base or body region of said transistor and said buried region, and said low concentration region has an impurity concentration, which is higher than that in said drift region.

6. The semiconductor device according to claim 1, wherein the impurity concentration in said low concentration region is not less than 5×10¹⁵ cm⁻³ and not more than 1×10¹⁷ cm⁻³.

7. The semiconductor device according to claim 1, wherein said portion is formed at a position so as to avoid contacting with an effective base or a body region which is formed when said transistor is in an operating state.

8. The semiconductor device according to claim 1, wherein a spacing in transverse direction between said base or said body region and said portion at the time said transistor is in non-operating state is wider than a spacing in layer-stacking direction between said base or said body region and said buried region at the time said transistor is in non-operating state.

9. The semiconductor device according to claim 1, further comprising a preventing region formed between said portion and the base or body region of said transistor, said preventing region preventing an extension of said base or body region.

10. The semiconductor device according to claim 9, wherein said preventing region is composed of an insulating material.

11. The semiconductor device according to claim 9, wherein said preventing region is composed of an impurity material of first conductivity type.

12. A semiconductor device including a transistor, comprising:
a semiconductor substrate;
a drift region of a first conductivity type formed on said semiconductor substrate;
a buried region of the first conductivity type formed between said semiconductor substrate and said drift region, said buried region having higher impurity concentration than said drift region;
a collector or drain region of the first conductivity type formed on a front plane of said drift region;
a base or body region of a second conductivity type; and
an emitter or source region of the first conductivity type,
wherein a coupling region of a first conductivity type is formed on a path including said collector or drain region and said buried region, said coupling region containing a first conductivity type impurity at a concentration lower than said collector or drain region or said buried region and higher than said drift region.

13. The semiconductor device according to claim 12, wherein a relationship of:
C_{d}/C_{c}≧10
is satisfied,
where C_{c} is a concentration of the impurity in said coupling region and C_{d} is a peak impurity concentration in said buried region.

14. The semiconductor device according to claim 12, wherein the impurity concentration in said coupling region is not less than 5×10¹⁵ cm⁻³ and not more than 1×10¹⁷ cm⁻³.

15. The semiconductor device according to claim 12, wherein said buried region is formed as being divided into a plurality of fragments along said path, and wherein said coupling region is formed between said plurality of fragments of said buried regions.

16. The semiconductor device according to claim 12, wherein said coupling region is formed at a position so as to make no contact with an effective base or a body region which is formed when said transistor is in an operating state.

17. The semiconductor device according to claim 1, wherein said transistor is an electrostatic discharge (ESD) protection circuit.

18. The semiconductor device according to claim 12, wherein said transistor is an electrostatic discharge (ESD) protection circuit.
